(19) United States
(12) Patent Application Publication
(10) Pub. No.: US 2026/0123480 A1
(43) Pub. Date: Apr. 30, 2026

(54) ISOLATION SEMICONDUCTOR PACKAGES WITH EXTENDED CONDUCTIVE TERMINALS

(71) Applicant: TEXAS INSTRUMENTS INCORPORATED, Dallas, TX (US)

(72) Inventors: Sylvester ANKAMAH-KUSI, McKinney, TX (US); Enis TUNCER, Dallas, TX (US); Jaimal Mallory WILLIAMSON, McKinney, TX (US); Guangxu LI, Allen, TX (US); Rajen Manicon MURUGAN, Dallas, TX (US)

(21) Appl. No.: 18/934,063

(22) Filed: Oct. 31, 2024

(51) Int. Cl. H01L 23/498; H01L 21/48; H01L 21/56; H01L 23/00; H01L 23/64; H01L 25/00; H01L 25/065

(52) U.S. Cl. CPC H10W 70/65; H10W 44/501; H10W 70/093; H10W 70/635; H10W 74/016; H10W 90/00; H10W 90/701; H10W 90/724

(57) ABSTRACT

In examples, a semiconductor package includes a first semiconductor die configured to operate in a first voltage domain; a second semiconductor die configured to operate in a second voltage domain; a substrate including a first metallization coupled to the first semiconductor die, a second metallization coupled to the second semiconductor die, and a build-up film between and physically contacting the first and second metallizations, the first metallization including a first conductive terminal extending through a first lateral surface of the build-up film, and the second metallization including a second conductive terminal extending through a second lateral surface of the build-up film opposite the first lateral surface; and a dielectric layer physically contacting a surface of the substrate facing away from the first and second semiconductor dies, the first and second conductive terminals located closer to the first and second semiconductor dies than a horizontal plane defined by the dielectric layer.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure may be subsequently covered with a mold compound to produce a package.

### SUMMARY

In examples, a semiconductor package includes a first semiconductor die configured to operate in a first voltage domain; a second semiconductor die configured to operate in a second voltage domain; a substrate including a first metallization coupled to the first semiconductor die, a second metallization coupled to the second semiconductor die, and a build-up film between and physically contacting the first and second metallizations, the first metallization including a first conductive terminal extending through a first lateral surface of the build-up film, and the second metallization including a second conductive terminal extending through a second lateral surface of the build-up film opposite the first lateral surface; and a dielectric layer physically contacting a surface of the substrate facing away from the first and second semiconductor dies, the first and second conductive terminals located closer to the first and second semiconductor dies than a horizontal plane defined by the dielectric layer.

In examples, a method for manufacturing a semiconductor package includes forming a substrate strip by iteratively plating a metal layer, applying build-up film to the metal layer, and thinning the build-up film, the substrate strip including first and second metallizations configured to operate in separate voltage domains and third and fourth metallizations configured to operate in separate voltage domains, each of the first, second, third, and fourth metallizations including an elongate conductive terminal extending along a bottom surface of the substrate strip, the conductive terminals of the second and third metallizations coupled to each other. The method includes coupling semiconductor dies to the first, second, third, and fourth metallizations; applying a mold compound layer on the semiconductor dies; applying a dielectric layer to the bottom surface of the substrate strip, the dielectric layer physically contacting the conductive terminals of the first, second, third, and fourth metallizations; forming openings in the mold compound layer, the dielectric layer, and the build-up film to expose the conductive terminals of the first, second, third, and fourth metallizations; and separating the conductive terminals of the second and third metallizations from each other.

### BRIEF DESCRIPTION OF THE DRAWINGS

FIG. 1A is a profile, cross-sectional view of an isolation semiconductor package with extended conductive terminals, in accordance with various examples.

FIG. 1B is a top-down view of an isolation semiconductor package with extended conductive terminals, in accordance with various examples.

FIG. 1C is a perspective view of an isolation semiconductor package with extended conductive terminals, in accordance with various examples.

FIG. 2 is a flow diagram of a method for manufacturing an isolation semiconductor package with extended conductive terminals, in accordance with various examples.

FIG. 3A1 is a profile, cross-sectional view of a portion of a process flow for manufacturing an isolation semiconductor package with extended conductive terminals, in accordance with various examples.

FIG. 3A2 is a top-down view of a portion of a process flow for manufacturing an isolation semiconductor package with extended conductive terminals, in accordance with various examples.

FIG. 3B1 is a profile, cross-sectional view of a portion of a process flow for manufacturing an isolation semiconductor package with extended conductive terminals, in accordance with various examples.

FIG. 3B2 is a top-down view of a portion of a process flow for manufacturing an isolation semiconductor package with extended conductive terminals, in accordance with various examples.

FIG. 3C1 is a profile, cross-sectional view of a portion of a process flow for manufacturing an isolation semiconductor package with extended conductive terminals, in accordance with various examples.

FIG. 3C2 is a top-down view of a portion of a process flow for manufacturing an isolation semiconductor package with extended conductive terminals, in accordance with various examples.

FIG. 3D1 is a profile, cross-sectional view of a portion of a process flow for manufacturing an isolation semiconductor package with extended conductive terminals, in accordance with various examples.

FIG. 3D2 is a top-down view of a portion of a process flow for manufacturing an isolation semiconductor package with extended conductive terminals, in accordance with various examples.

FIG. 3E1 is a profile, cross-sectional view of a portion of a process flow for manufacturing an isolation semiconductor package with extended conductive terminals, in accordance with various examples.

FIG. 3E2 is a top-down view of a portion of a process flow for manufacturing an isolation semiconductor package with extended conductive terminals, in accordance with various examples.

FIG. 3F1 is a profile, cross-sectional view of a portion of a process flow for manufacturing an isolation semiconductor package with extended conductive terminals, in accordance with various examples.

FIG. 3F2 is a top-down view of a portion of a process flow for manufacturing an isolation semiconductor package with extended conductive terminals, in accordance with various examples.

FIG. 3G1 is a profile, cross-sectional view of a portion of a process flow for manufacturing an isolation semiconductor package with extended conductive terminals, in accordance with various examples.

FIG. 3G2 is a top-down view of a portion of a process flow for manufacturing an isolation semiconductor package with extended conductive terminals, in accordance with various examples.

FIG. 4A1 is a profile, cross-sectional view of an isolation semiconductor package with extended conductive terminals coupled to a printed circuit board, in accordance with various examples.

FIG. 4A2 is a top-down view of an isolation semiconductor package with extended conductive terminals coupled to a printed circuit board, in accordance with various examples.

FIG. 4A3 is a perspective view of an isolation semiconductor package with extended conductive terminals coupled to a printed circuit board, in accordance with various examples.

FIG. 5A1 is a profile, cross-sectional view of an isolation semiconductor package with extended conductive terminals coupled to a printed circuit board, in accordance with various examples.

FIG. 5A2 is a top-down view of an isolation semiconductor package with extended conductive terminals coupled to a printed circuit board, in accordance with various examples.

FIG. 5A3 is a perspective view of an isolation semiconductor package with extended conductive terminals coupled to a printed circuit board, in accordance with various examples.

FIG. 6 is a graph showing the efficacy of an isolation semiconductor package with extended conductive terminals, in accordance with various examples.

FIG. 7 is a block diagram of an electronic device including an isolation semiconductor package with extended conductive terminals, in accordance with various examples.

### DETAILED DESCRIPTION

Semiconductor packages may include semiconductor dies that are coupled to substrates. A substrate may include one or more metal components and dielectrics covering the one or more metal components. The metal components provide electrical pathways from a top surface of the substrate (e.g., to which the semiconductor die(s) are coupled) to a bottom surface of the substrate (e.g., to which a printed circuit board (PCB) or other electrical component(s) are coupled).

Some semiconductor packages contain components that operate in distinct voltage domains. For example, a semiconductor package may include two semiconductor dies, with one of the semiconductor dies operating at relatively high voltages and the other semiconductor die operating at relatively low voltages. These semiconductor dies, as well as metal components within the package (e.g., in the substrate) that are coupled to these semiconductor dies, are kept separate from each other. This separation is generally referred to as isolation, which means that a first semiconductor die and the metallization coupled to that first semiconductor die collectively operate in a first voltage domain that is electrically isolated from a second semiconductor die which operates in a second voltage domain and the metallization coupled to that second semiconductor die. The operating voltage for each of the different voltage domains can range from 1V to 30k V.

Within the substrate, an electric field forms between the isolated metallizations. This electric field imparts stress to the dielectric that separates the metallizations. If the electric field becomes adequately strong, the dielectric breaks down, resulting in a short between the isolated metallizations and effectively ending the isolation. When the metallizations are no longer isolated, device failure results.

To prevent such dielectric breakdown, the substrate is manufactured with an adequately strong dielectric material that can withstand strong electric fields. However, there is a second possibility for dielectric breakdown outside of the package. Specifically, the air outside of the package serves as another dielectric, and when this air outside of the package is subjected to the strong electric fields being generated from within the package, the air may break down, resulting in device failure. To mitigate the risk of the air dielectric breaking down, a solid dielectric layer may be coupled to the bottom surface of the substrate. The dielectric layer has a higher dielectric constant than air, and thus the dielectric layer is better able to withstand the strong electric field that would otherwise break down the air. However, such a solid dielectric layer can be inadequate when subjected to particularly high electric fields, and in such cases, the solid dielectric layer may break down, resulting in device failure.

This description presents various examples of a semiconductor package including an isolation substrate having conductive terminals (e.g., leads) extending laterally away from the isolation substrate. By extending laterally away from the isolation substrate, the conductive terminals, which are in separate voltage domains, spread the electric field over a larger volume of space, thus weakening the electric field and mitigating the risk of dielectric breakdown outside of the semiconductor package. Further, by creating a large distance between the points at which the conductive terminals couple to a PCB, the creepage distance along the bottom surface of the semiconductor package is increased (i.e., the surface along which current must creep to cause a short is increased), thus mitigating the risk of breakdown along the surface of the semiconductor package. In some examples, a semiconductor package includes a first semiconductor die configured to operate in a first voltage domain and a second semiconductor die configured to operate in a second voltage domain. The semiconductor package includes a substrate including a first metallization coupled to the first semiconductor die, a second metallization coupled to the second semiconductor die, and a build-up film between and physically contacting the first and second metallizations, with the first metallization including a first conductive terminal extending through a first lateral surface of the build-up film, and with the second metallization including a second conductive terminal extending through a second lateral surface of the build-up film opposite the first lateral surface. The semiconductor package also includes a dielectric layer physically contacting a surface of the substrate facing away from the first and second semiconductor dies, with the first and second conductive terminals located closer to the first and second semiconductor dies than a horizontal plane defined by the dielectric layer.

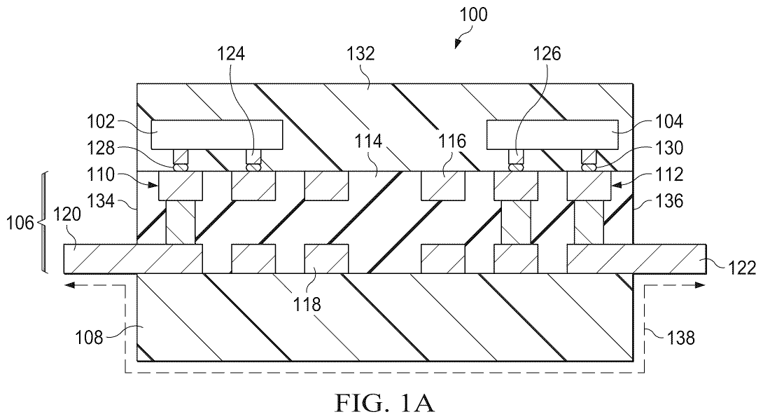

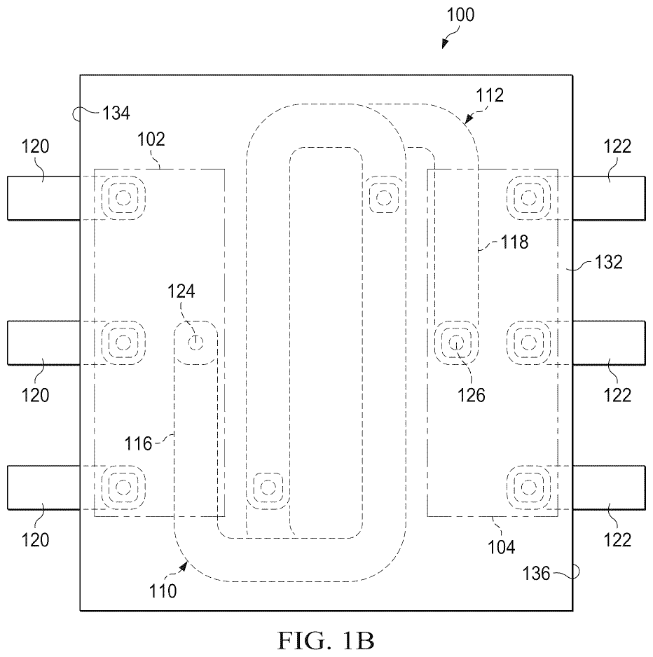

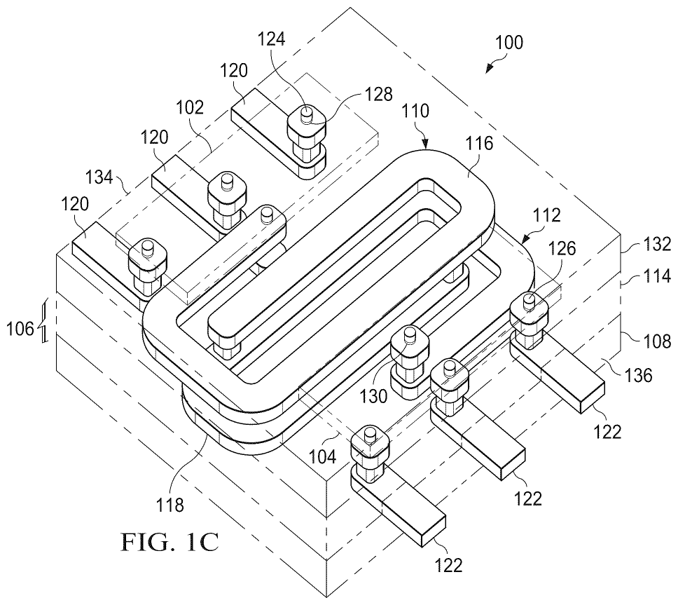

FIG. 1A is a profile, cross-sectional view of an isolation semiconductor package 100 with extended conductive terminals, in accordance with various examples. FIG. 1B is a top-down view of the isolation semiconductor package 100, in accordance with various examples. FIG. 1C is a perspective view of the isolation semiconductor package 100, in accordance with various examples. In particular, the example semiconductor package 100 includes a semiconductor die 102, a semiconductor die 104, a substrate 106, and a dielectric layer 108. The substrate 106 may include a metallization 110, a metallization 112, and a dielectric layer 114. The metallization 110 includes a coil 116 and the metallization 112 includes a coil 118. The metallization 110 includes a conductive terminal 120 (e.g., a lead) and the metallization 112 includes a conductive terminal 122 (e.g., a lead). The semiconductor package 100 also includes metal posts 124 and 126, and solder joints 128 and 130. The semiconductor package 100 also includes a mold compound 132.

In examples, the semiconductor die 102 is coupled to the metallization 110 by the metal posts 124 and the solder joints 128. The solder joints 128 may be coupled to the coil 116, for example. The semiconductor die 104 may be coupled to the metallization 112 by the metal posts 126 and the solder joints 130. The solder joints 130 may be coupled to the coil 118, for example. The mold compound 132 is between and physically contacts the semiconductor dies 102 and 104, the metal posts 124 and 126, and the solder joints 128 and 130. The dielectric layer 114, which may be a build-up film (e.g., an AJINOMOTO® build-up film) including an epoxy resin, filler materials (e.g., ceramic filler particles), and a curing agent, may be between and may physically contact the metallizations 110, 112. The metallization 110 is exposed to top and bottom opposing surfaces of the dielectric layer 114, and the metallization 112 is also exposed to top and bottom opposing surfaces of the dielectric layer 114. The dielectric layer 108 physically contacts the bottom surface of the dielectric layer 114, including the portions of the metallizations 110, 112 that are exposed to the bottom surface of the dielectric layer 114. The dielectric layer 108 may be a build-up film (e.g., AJINOMOTO® build-up film) including an epoxy resin, filler materials (e.g., ceramic filler particles), and a curing agent. Alternatively, the dielectric layer 108 may be a mold compound. Other types of dielectrics for the dielectric layer 108 are contemplated and included in the scope of this disclosure.

The metallizations 110, 112 may be configured to operate in separate voltage domains. Because the semiconductor die 102 is coupled to the metallization 110 and the semiconductor die 104 is coupled to the metallization 112, the semiconductor dies 102, 104 are also configured to operate in separate voltage domains. The semiconductor die 102 may operate in the same voltage domain as the metallization 110, and the semiconductor die 104 may operate in the same voltage domain as the metallization 112. Because the metallizations 110, 112 are in separate voltage domains, the metallizations 110, 112 cannot come into physical contact with each other, so that electrical isolation is maintained. More particularly, in the dielectric layer 114, the metallizations 110, 112 may be separated from each other by a minimum distance so that the electric field between the metallizations 110, 112 is not strong enough to cause breakdown of the dielectric layer 114. Within the substrate 106, this minimum distance between the metallizations 110, 112 is defined as:

$$distance > \frac{voltage between metallizations}{dielectric breakdown voltage} \qquad ( 1 )$$

with a distance between the metallizations 110, 112 less than this minimum threshold resulting in breakdown of the dielectric layer 114, and device failure. A minimum distance between the first and second metallizations 110, 112 within the substrate 106 is also related to a maximum operating voltage of the semiconductor package 100 by the expression (1).

The electric field between the metallizations 110, 112 may extend into the air below the dielectric layer 114. The electric field may be so strong that the air dielectric breaks down and causes device failure. To prevent breakdown of the air dielectric below the dielectric layer 114, the dielectric layer 108 is coupled to the bottom surface of the dielectric layer 114. To enable the dielectric layer 108 to prevent air dielectric breakdown, the thickness of the dielectric layer 108 is defined as:

$$thickness of dielectric > \frac{voltage between metallizations}{air dielectric breakdown voltage} \qquad ( 2 )$$

A minimum thickness of the dielectric layer 108 is related to a maximum operating voltage of the semiconductor package by the expression (2).

Further, to prevent air dielectric breakdown, the dielectric layer 108 has a dielectric constant that is significantly greater than that of air, and thus the electric field cannot cause breakdown of the air dielectric in the spatial region where the dielectric layer 108 is located. The dielectric constant of the dielectric layer 108 ranges from 3 to 4, with a dielectric constant below this range being disadvantageous because the dielectric must tolerate a substantially higher electric field, and with a dielectric constant above this range being disadvantageous because it introduces an unacceptably high amount of capacitance. The mold compound 132 is present on the top surface of the dielectric layer 114, and thus air dielectric breakdown is not a risk in this region.

The four lateral surfaces of the dielectric layer 108 are vertically aligned with the respective four lateral surfaces of the substrate 106 (i.e., of the dielectric layer 114).

The conductive terminal 120 extends outward through a lateral surface 134 of the dielectric layer 114 (i.e., of the substrate 106), perpendicularly through the lateral surface 134, which is critical to achieve adequate isolation. The conductive terminal 120 is closer to the semiconductor dies 102, 104 than the horizontal plane defined by the dielectric layer 108. The conductive terminal 122 extends outward through a lateral surface 136 of the dielectric layer 114 (i.e., of the substrate 106), perpendicularly through the lateral surface 136, which is critical to achieve adequate isolation. The conductive terminal 122 is closer to the semiconductor dies 102, 104 than the horizontal plane defined by the dielectric layer 108. The conductive terminal 120 has a length that is measured from the lateral surface 134 to a distal end of the conductive terminal 120. The conductive terminal 122 has a length that is measured from the lateral surface 136 to a distal end of the conductive terminal 122. The conductive terminals 120 and 122 cause the electric field between the metallizations 110, 112 to spread apart because the conductive terminals 120 and 122 extend outside of the semiconductor package 100 and in opposing directions. Because the electric field is spread over a larger region, the electric field weakens, and this mitigates the risk of dielectric breakdown and device failure. More specifically, the weakened electric field caused by the presence of the conductive terminals 120 and 122 outside of the semiconductor package 100 and extending in opposing directions may reduce the risk of dielectric breakdown in the air, in the dielectric layer 108, and/or in the dielectric layer 114. To mitigate this risk, each of the conductive terminals 120 and 122 has a length ranging from 300 microns to 600 microns as measured from the lateral surfaces 134 and 136, respectively, to distal ends of the conductive terminals 120 and 122, respectively. Lengths of the conductive terminals 120, 122 lower than this range are disadvantageous because it reduces isolation, and lengths of the conductive terminals 120, 122 greater than this range are disadvantageous because they occupy an unacceptably large amount of space.

The conductive terminals 120, 122 reduce the risk of air dielectric breakdown as described above. The conductive terminals 120, 122 also reduce the risk of breakdown along the surface of the semiconductor package 100 by increasing the connection point-to-connection point creepage distance 138 along the bottom of the semiconductor package 100. More specifically, without the presence of the dielectric layer 108 and the extended conductive terminals 120, 122, the distance along the bottom surface of the semiconductor package 100 between the points at which the semiconductor package 100 would couple to a PCB would be relatively small, providing for a short creepage distance and a greater risk of breakdown along the bottom surface of the semiconductor package 100. However, because of the presence of the dielectric layer 108 and the extended conductive terminals 120, 122, the creepage distance 138 is relatively increased, thereby significantly mitigating the risk of breakdown along the bottom surface of the semiconductor package 100.

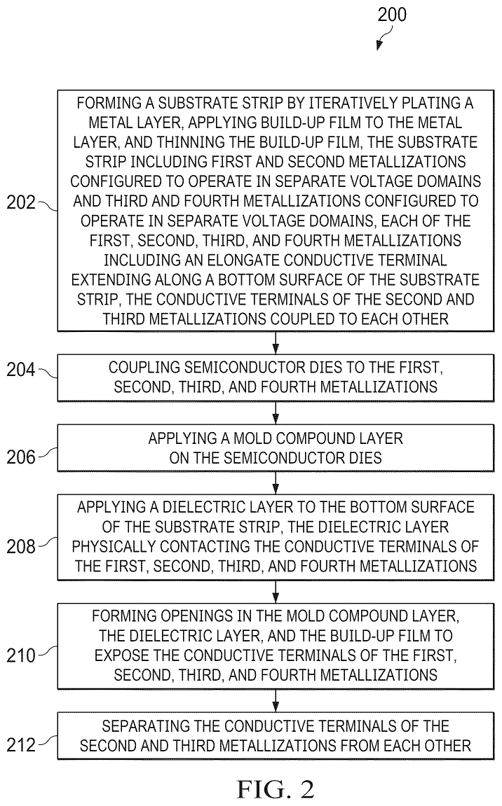

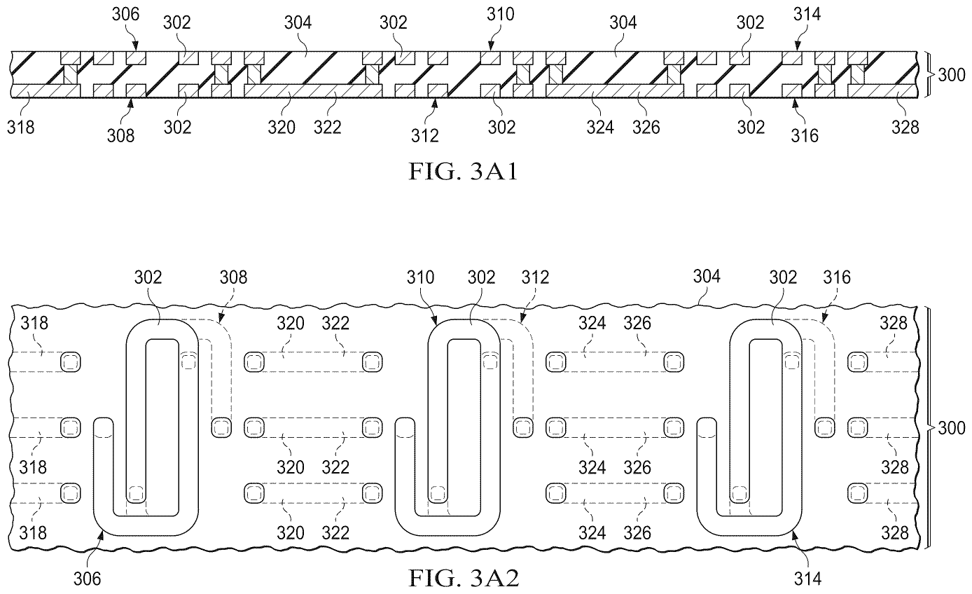

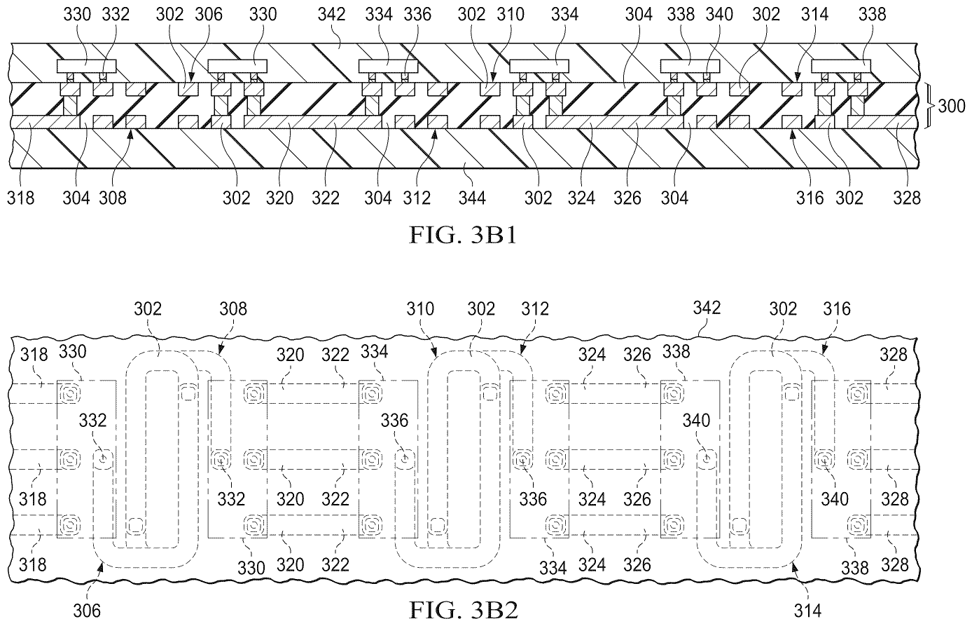

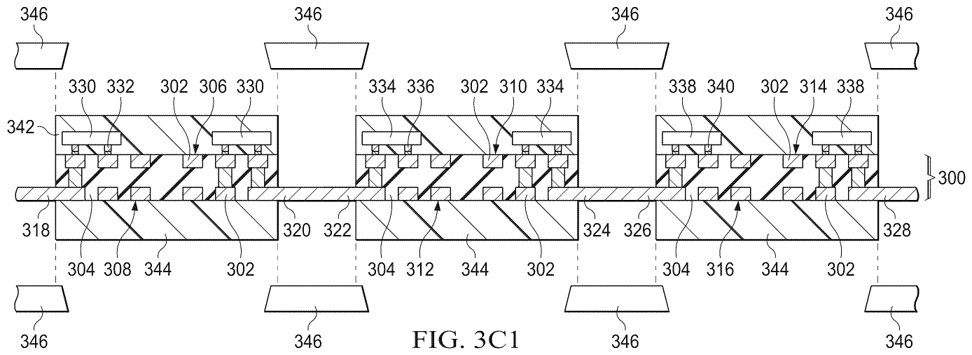

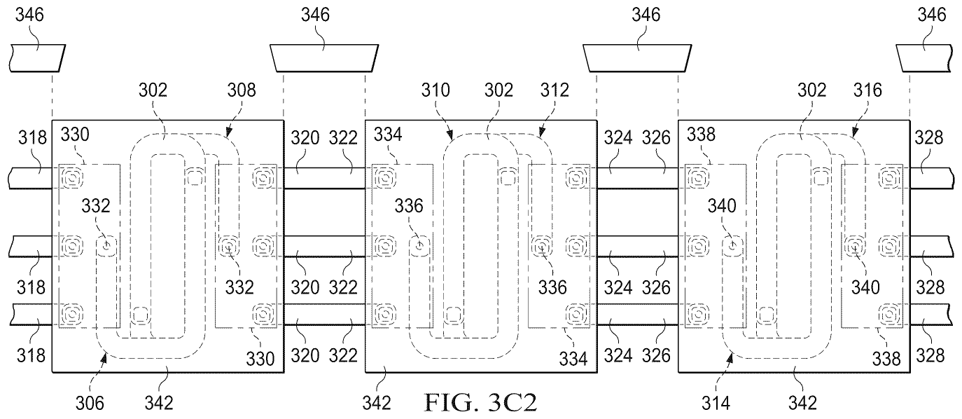

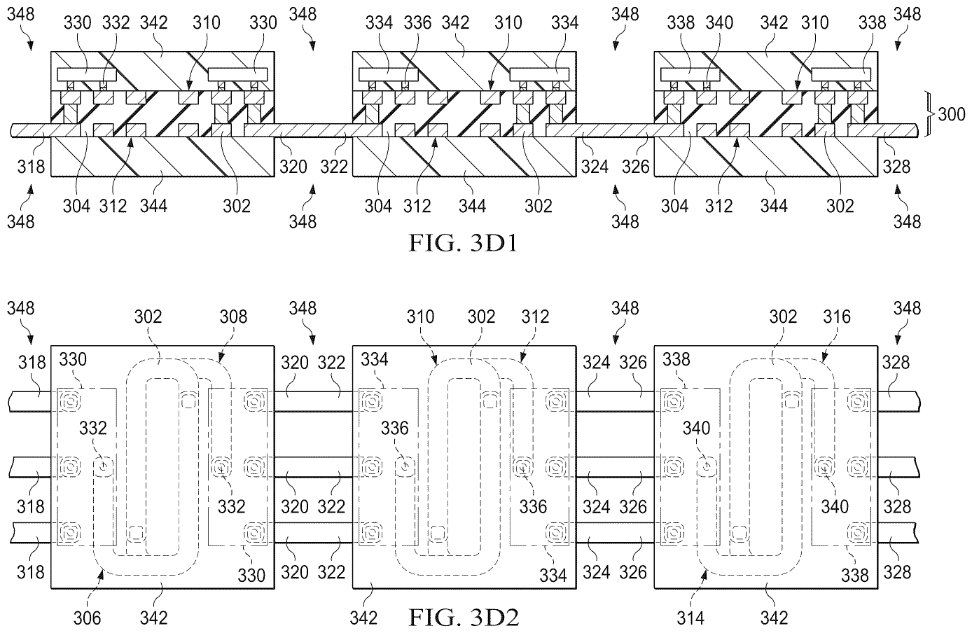

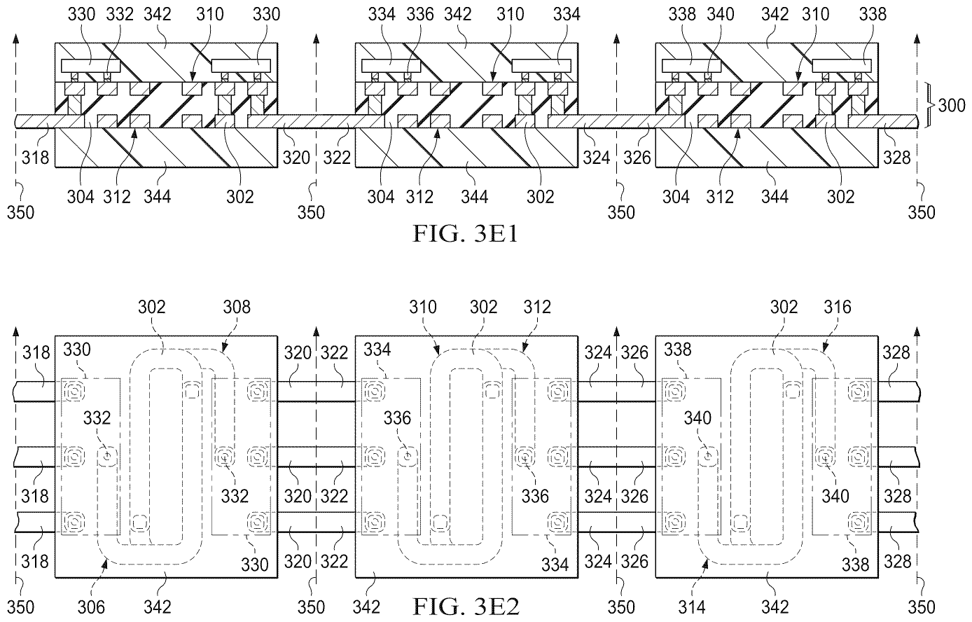

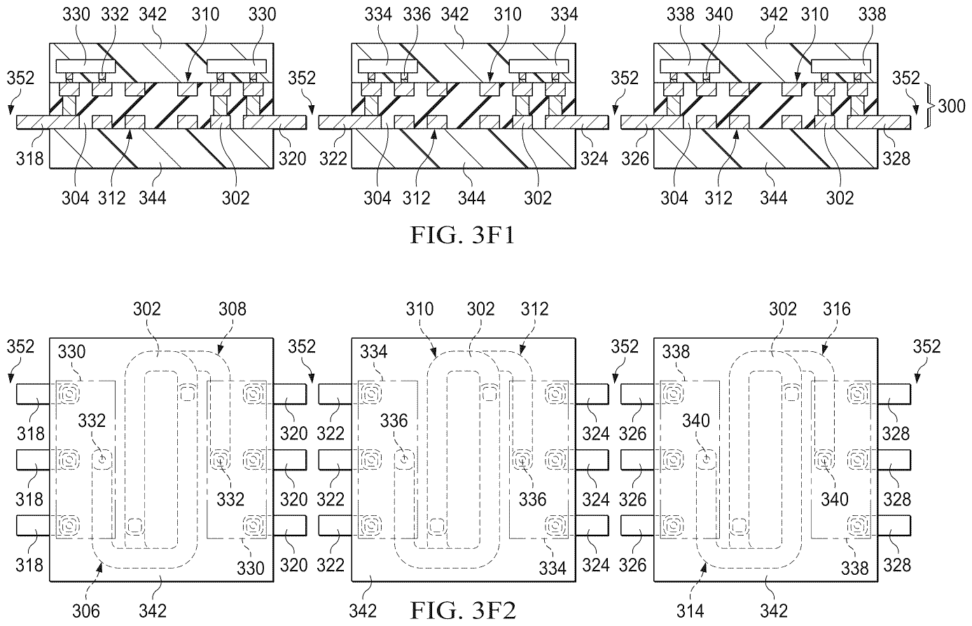

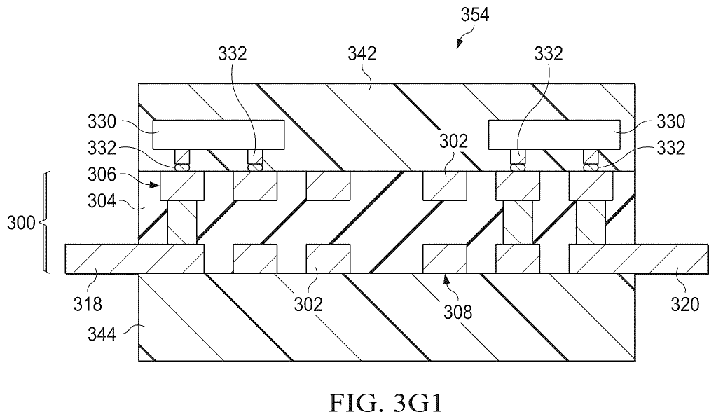

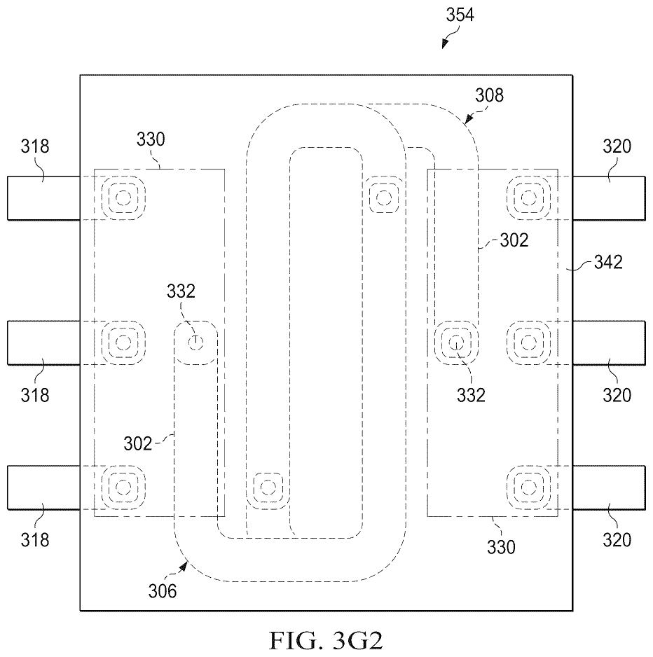

FIG. 2 is a flow diagram of a method 200 for manufacturing an isolation semiconductor package with extended conductive terminals, in accordance with various examples. FIG. 3A1-5A3 are a process flow for manufacturing an isolation semiconductor package with extended conductive terminals, in accordance with various examples. Accordingly, FIGS. 2 and 3A1-5A3 are now described in parallel.

The method 200 may include forming a substrate strip by iteratively plating a metal layer, applying build-up film (e.g., AJINOMOTO® build-up film) including an epoxy resin, filler materials (e.g., ceramic filler materials), and a curing agent, to the metal layer, and thinning the build-up film (202). The substrate strip includes first and second metallizations configured to operate in separate voltage domains and third and fourth metallizations configured to operate in separate voltage domains (202). Each of the first, second, third, and fourth metallizations includes an elongate conductive terminal extending along a bottom surface of the substrate strip (202). The conductive terminals of the second and third metallizations are coupled to each other (202). FIG. 3A1 is a cross-sectional view of a substrate strip 300 manufactured by the iterative process described above, in which a metal layer 302 (or corresponding metal via) is plated (e.g., on a base seed layer, or on a previously plated metal layer or via), a build-up film 304 or other dielectric is applied and thinned such that the top surfaces of the most-recently-plated metal layer or via is exposed, and then the process may be repeated until a target number of metal layers and/or metal vias have been formed in the substrate strip 300. The completed substrate strip 300 includes metallizations 306, 308, 310, 312, 314, and 316 (although the method 200 expressly mentions four metallizations, any number of metallizations may be included). After the manufacturing method 200 is complete, these metallizations 306, 308, 310, 312, 314, and 316 will be electrically separate from each other, but during at least some manufacturing steps, conductive terminals of the metallizations may be coupled to each other. For example, the metallizations 306 and 308 may include conductive terminals 318 and 320, respectively; the metallizations 310 and 312 may include conductive terminals 322 and 324, respectively; and the metallizations 314 and 316 may include conductive terminals 326 and 328, respectively, with the conductive terminals 320 and 322 coupled to each other, and the conductive terminals 324 and 326 coupled to each other. FIG. 3A2 is a top-down view of the structure of FIG. 3A1.

The method 200 may include coupling semiconductor dies to the first, second, third, and fourth metallizations (204). The method 200 may include applying a mold compound layer on the semiconductor dies (206). The method 200 may include applying a dielectric layer to the bottom surface of the substrate strip, with the dielectric layer physically contacting the conductive terminals of the first, second, third, and fourth metallizations (208). FIG. 3B1 is a cross-sectional view of the structure of FIG. 3A1, except that a semiconductor die 330 is coupled to the substrate strip 300 by metal posts 332, a semiconductor die 334 is coupled to the substrate strip 300 by metal posts 336, and a semiconductor die 338 is coupled to the substrate strip 300 by metal posts 340. A mold compound 342 covers and physically contacts the semiconductor dies 330, 334, and 338, the metal posts 332, 336, and 340, and the substrate strip 300. Further, a dielectric layer 344 is coupled to a bottom surface of the substrate strip 300. The dielectric layer 344 may have the properties of the dielectric layer 108 described above. The dielectric layer 344 physically contacts the conductive terminals 318, 320, 322, 324, 326, and 328. FIG. 3B2 is a top-down view of the structure of FIG. 3B1.

The method 200 may include forming openings in the mold compound layer, the dielectric layer, and the build-up film to expose the conductive terminals of the first, second, third, and fourth metallizations (210). FIG. 3C1 is a cross-sectional view of the structure of FIG. 3B1, and FIG. 3D1 is a cross-sectional view of the structure of FIG. 3C1, except that a laser ablation is performed to create openings 348, as numeral 346 indicates. The width of the laser cuts are such that the conductive terminals that are exposed in the openings 348 have twice the conductive terminal lengths provided above. FIG. 3C2 is a top-down view of the structure of FIG. 3C1. FIG. 3D2 is a top-down view of the structure of FIG. 3D1.

The method 200 may include separating the conductive terminals of the second and third metallizations from each other (212). FIG. 3E1 is a cross-sectional view of the structure of FIG. 3D1, except that the conductive terminals exposed in the openings 348 are being cut, for example, by a mechanical or laser saw, as numeral 350 indicates. FIG. 3E2 is a top-down view of the structure of FIG. 3E1, in accordance with various examples. FIG. 3F1 is a cross-sectional view of the structure of FIG. 3E1, except that the conductive terminals in the openings 348 are fully sawn, as numeral 352 indicates. FIG. 3F2 is a top-down view of the structure of FIG. 3F1. FIG. 3G1 and FIG. 3G2 are cross-sectional and top-down views of an individual semiconductor package 354 produced using the method 200. The semiconductor package 354 is an example of the semiconductor package 100.

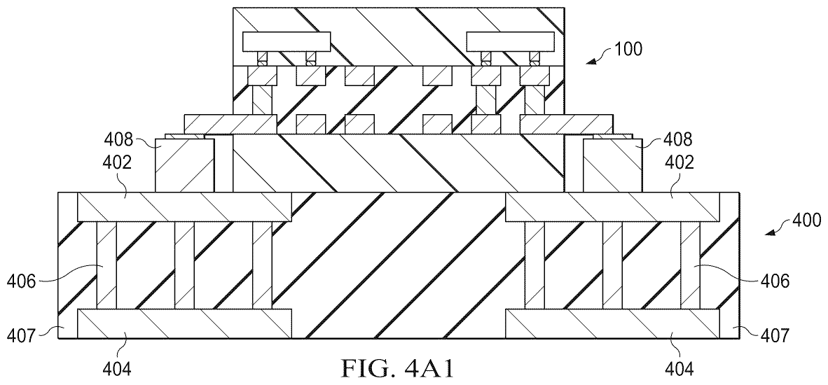

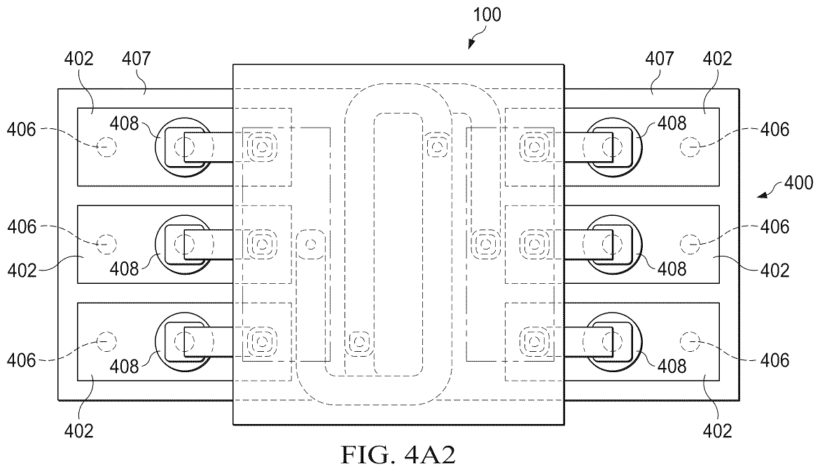

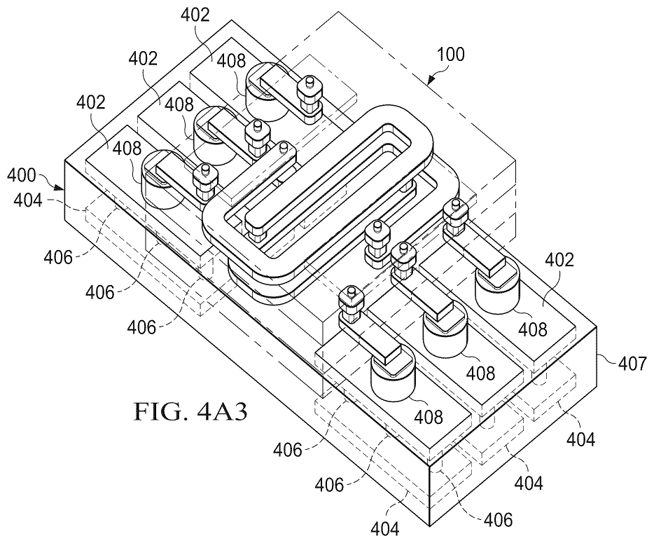

After manufacture, the semiconductor package 100 (e.g., the semiconductor package 354) may be coupled to a printed circuit board (PCB). FIG. 4A1 is a cross-sectional view of an example semiconductor package 100 coupled to a PCB 400. The PCB 400 may include a metal layer 402, a metal layer 404, vias 406 coupled between the metal layers 402 and 404, and a dielectric 407. The PCB 400 may include metal bumps 408 on a top surface of the PCB 400, to which the conductive terminals of the semiconductor package 100 may be coupled (e.g., soldered). The metal bumps 408 may be sufficiently thick that the bottom surface of the semiconductor package 100 physically contacts a top surface of the PCB 400 or is suspended above the top surface of the PCB 400. FIG. 4A2 is a top-down view of the structure of FIG. 4A1. FIG. 4A3 is a perspective view of the structure of FIG. 4A1.

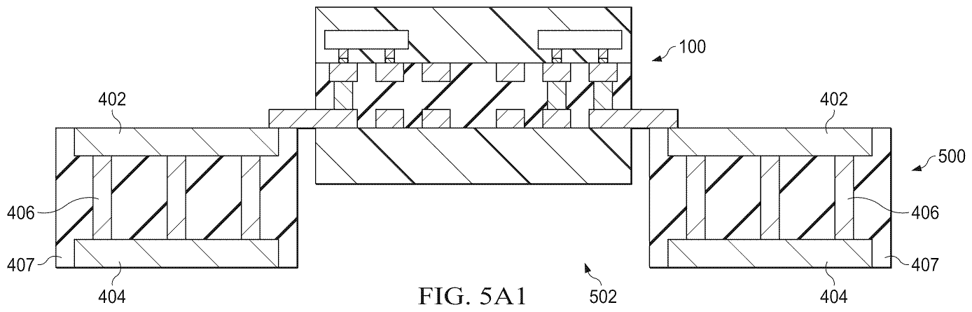

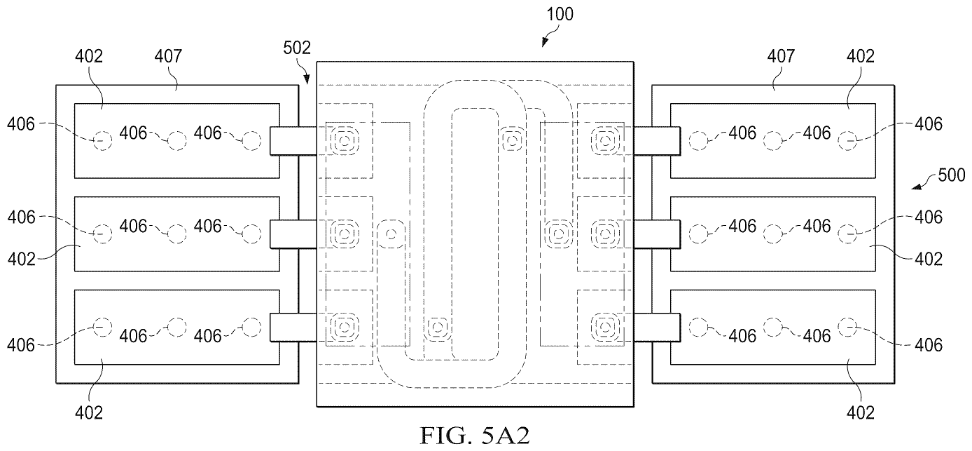

FIG. 5A1 is a cross-sectional view of an example semiconductor package 100 coupled to a PCB 500. The PCB 500 differs from the PCB 400 in that the PCB 500 lacks the metal bumps 408, and the PCB 500 includes a cavity 502 extending through a thickness of the PCB 500. The cavity 502 may have a rectangular (e.g., square) shape when viewed from above or below (i.e., in the horizontal plane). The conductive terminals of the semiconductor package 100 may be coupled to the metal layer 402 (e.g., by solder), and the body of the semiconductor package 100 may be suspended in the cavity 502. In this way, the combination of the semiconductor package 100 and the PCB 500 occupies relatively less space, and the semiconductor package 100 may expel heat more effectively. FIG. 5A2 is a top-down view of the structure of FIG. 5A1. FIG. 5A3 is a perspective view of the structure of FIG. 5A1.

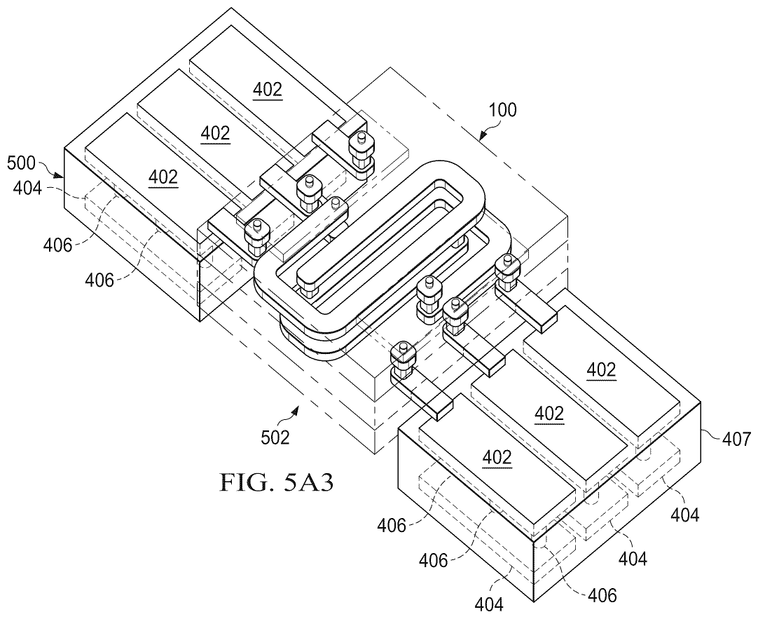

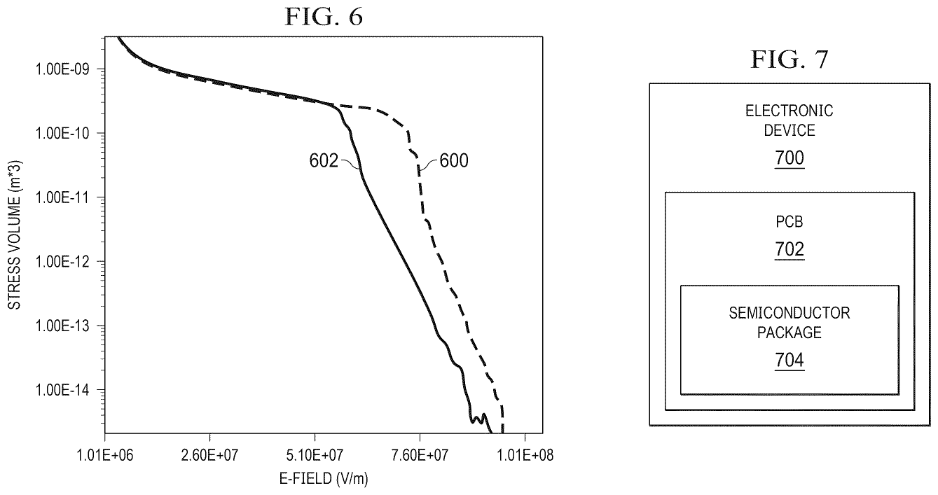

FIG. 6 is a graph showing the efficacy of an isolation semiconductor package with extended conductive terminals, in accordance with various examples. The graph includes electric field in volts per meter on the x-axis, and stress volume in microns³ on the y-axis. The graph includes a curve 600, which represents a different solution, and a curve 602, which represents the semiconductor package 100. As shown, for stronger electric fields (e.g., approximately 5.4E+07 V/m and higher), the curve 602 shows a smaller stress volume, demonstrating the substantially greater efficacy of the semiconductor package 100 relative to other solutions.

FIG. 7 is a block diagram of an electronic device 700 including an isolation semiconductor package with extended conductive terminals, in accordance with various examples. The electronic device 700 may include a PCB 702 (e.g., PCB 400 or 500) and a semiconductor package 704 (e.g., semiconductor package 100) coupled to the PCB 702. Examples of the electronic device 700 include an automobile, an aircraft, a watercraft, a spacecraft, a video game console, an arcade video game unit, a smartphone, an entertainment device, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims. As used herein, the terms “terminal,” “node,” “interconnection,” “pin,” and “lead” are used interchangeably.

What is claimed is:

1. A semiconductor package, comprising:
a first semiconductor die configured to operate in a first voltage domain;
a second semiconductor die configured to operate in a second voltage domain;
a substrate including a first metallization coupled to the first semiconductor die, a second metallization coupled to the second semiconductor die, and a build-up film between and physically contacting the first and second metallizations, the first metallization including a first conductive terminal extending through a first lateral surface of the build-up film, and the second metallization including a second conductive terminal extending through a second lateral surface of the build-up film opposite the first lateral surface; and
a dielectric layer physically contacting a surface of the substrate facing away from the first and second semiconductor dies, the first and second conductive terminals located closer to the first and second semiconductor dies than a horizontal plane defined by the dielectric layer.

2. The semiconductor package of claim 1, wherein the dielectric layer has a dielectric constant ranging between 3 and 4.

3. The semiconductor package of claim 1, wherein the dielectric layer comprises a build-up film including an epoxy resin, ceramic filler particles, and a curing agent.

4. The semiconductor package of claim 1, wherein the dielectric layer includes a mold compound.

5. The semiconductor package of claim 1, wherein a minimum thickness of the dielectric layer is greater than a voltage across the dielectric layer divided by a breakdown voltage of the dielectric layer.

6. The semiconductor package of claim 1, wherein the first and second conductive terminals have lengths ranging from 300 microns to 600 microns.

7. The semiconductor package of claim 1, wherein the first and second metallizations belong to the first and second voltage domains, respectively.

8. The semiconductor package of claim 1, wherein the first conductive terminal extends through the first lateral surface perpendicularly to the first lateral surface, and wherein the second conductive terminal extends through the second lateral surface perpendicularly to the second lateral surface.

9. The semiconductor package of claim 1, wherein a minimum distance between the first and second metallizations within the substrate is greater than a voltage in the semiconductor package divided by a breakdown voltage of a dielectric material between the first and second metallizations.

10. A semiconductor package, comprising:
a first semiconductor die;
a second semiconductor die;
a substrate including a first metallization coupled to the first semiconductor die and configured to operate in a first voltage domain, a second metallization coupled to the second semiconductor die and configured to operate in a second voltage domain, and a build-up film covering the first and second metallizations, the first metallization including a first conductive terminal extending through a first lateral surface of the substrate, the second metallization including a second conductive terminal extending through a second lateral surface of the substrate; and
a dielectric layer coupled to a bottom surface of the substrate facing away from the first and second semiconductor dies, the dielectric layer having a dielectric constant ranging between 3 and 4, a first lateral surface of the dielectric layer vertically aligned with the first lateral surface of the substrate, and a second lateral surface of the dielectric layer vertically aligned with the second lateral surface of the substrate.

11. The semiconductor package of claim 10, wherein the dielectric layer comprises a build-up film including an epoxy resin, ceramic filler particles, and a curing agent.

12. The semiconductor package of claim 10, wherein the dielectric layer includes a mold compound.

13. The semiconductor package of claim 10, wherein a minimum thickness of the dielectric layer is greater than a voltage across the dielectric layer divided by a breakdown voltage of the dielectric layer.

14. The semiconductor package of claim 10, wherein the first and second conductive terminals have lengths ranging from 300 microns to 600 microns.

15. The semiconductor package of claim 10, wherein the first metallization includes a first coil and a second metallization includes a second coil.

16. The semiconductor package of claim 10, wherein a minimum distance between the first and second metallizations within the substrate is greater than a ratio of voltage between the first and second metallizations to a breakdown voltage of a dielectric between the first and second metallizations.

17. A method for manufacturing a semiconductor package, comprising:
forming a substrate strip by iteratively plating a metal layer, applying build-up film to the metal layer, and thinning the build-up film, the substrate strip including first and second metallizations configured to operate in separate voltage domains and third and fourth metallizations configured to operate in separate voltage domains, each of the first, second, third, and fourth metallizations including an elongate conductive terminal extending along a bottom surface of the substrate strip, the conductive terminals of the second and third metallizations coupled to each other;
coupling semiconductor dies to the first, second, third, and fourth metallizations;
applying a mold compound layer on the semiconductor dies;
applying a dielectric layer to the bottom surface of the substrate strip, the dielectric layer physically contacting the conductive terminals of the first, second, third, and fourth metallizations;
forming openings in the mold compound layer, the dielectric layer, and the build-up film to expose the conductive terminals of the first, second, third, and fourth metallizations; and
separating the conductive terminals of the second and third metallizations from each other.

18. The method of claim 17, wherein, in the substrate strip, the first and fourth metallizations do not couple to each other and do not couple to either of the second and third metallizations.

19. The method of claim 17, wherein, after forming the openings, the conductive terminals of the first and second metallizations extend through first and second lateral surfaces of the build-up film, respectively.

20. The method of claim 19, wherein the dielectric layer extends from the first lateral surface of the build-up film to the second lateral surface of the build-up film.

21. The method of claim 17, wherein, after the separating, the conductive terminal of the second metallization has a length ranging from 300 microns to 600 microns.
